(19) United States
(12) Patent Application Publication
(10) Pub. No.: US 2014/0016661 A1
(43) Pub. Date: Jan. 16, 2014

(54) SEMICONDUCTOR LIGHT-EMITTING ELEMENT AND LIGHT-EMITTING DEVICE USING THE SAME

(71) Applicant: PANASONIC CORPORATION, Osaka (JP)

(72) Inventors: Kenji ORITA, Osaka (JP); Kazuhiko YAMANAKA, Osaka (JP)

(73) Assignee: PANASONIC CORPORATION, Osaka (JP)

(21) Appl. No.: 14/024,588

(22) Filed: Sep. 11, 2013

Related U.S. Application Data
(63) Continuation of application No. PCT/JP2011/004224, filed on Jul. 26, 2011.

(30) Foreign Application Priority Data
Mar. 17, 2011 (JP) 2011-059192

(51) Int. Cl. H01S 5/026

(52) U.S. Cl. CPC H01S 5/026
USPC 372/50.1

(57) ABSTRACT

A semiconductor light-emitting element includes: a substrate; a semiconductor stacked film including a first cladding layer of a first conductivity type formed on the substrate, a light-emitting layer formed on the first cladding layer, and a second cladding layer of a second conductivity type formed on the light-emitting layer, and having an optical waveguide; a first electrode formed so as to be electrically connected to the first cladding layer; and a second electrode formed so as to be electrically connected to the second cladding layer. The light-emitting layer generates guided light that is guided in the optical waveguide, and non-guided light that is not guided in the optical waveguide, and the non-guided light is emitted from one of the substrate side and the semiconductor stacked layer side to the outside.

### CROSS-REFERENCE TO RELATED APPLICATION

This is a continuation of PCT International Application PCT/JP2011/004224 filed on Jul. 26, 2011, which claims priority to Japanese Patent Application No. 2011-059192 filed on Mar. 17, 2011. The disclosures of these applications including the specifications, the drawings, and the claims are hereby incorporated by reference in their entirety.

### BACKGROUND

The present invention relates to semiconductor light-emitting elements and light-emitting devices using the same, and more particularly to semiconductor light-emitting elements having an optical waveguide and light-emitting devices using the same.

Light-emitting diodes (LEDs), laser diodes (LDs), super luminescent diodes (SLDs), etc. having a semiconductor stacked film in which a P-type semiconductor, a light-emitting layer, and an N-type semiconductor are stacked are commonly known as semiconductor light-emitting elements. Among these semiconductor light-emitting elements, LEDs configured to emit red light having an emission wavelength close to 630 nm are widely used for switch lighting of electric and electronic equipment. LEDs configured to emit light having an emission wavelength of 370 nm to 480 nm form white LEDs in combination with phosphors that produce fluorescence having a fluorescent wavelength of around 550 nm. Such white LEDs are used for light sources for general household lighting, backlight light sources of liquid crystal display (LCD) televisions, and flash light sources of mobile electronic devices. On the other hand, LDs and SLDs have unique characteristics the LEDs do not have. The LEDs are the semiconductor light-emitting elements using spontaneous emission light produced by recombination of injected carriers, whereas the SLDs and the LDs have an optical waveguide and is capable of emitting stimulated emission light, namely spontaneous emission light amplified with gain due to stimulated emission while traveling in the optical waveguide toward a light-emitting end facet, from the light-emitting end facet. In particular, the LDs are capable of causing laser oscillation with the Fabry-Perot (FP) mode in optical cavities formed by front and rear facets of the optical waveguide. The LDs thus efficiently emit light, and are used for light sources of optical pickups, laser displays, etc. Unlike the LDs, the SLDs suppress formation of optical cavities due to end facet reflection so that no laser oscillation with the FP mode occurs. Thus, like LEDs, the SLDs have an incoherent property and a broad spectrum profile. The SLDs have been used in practical applications, where it provides light of optical output power of up to about several tens of milliwatts. To be more precise, SLDs are used in the field of, e.g., optical measurement such as optical fiber gyroscopes and optical coherence tomography (OCT), and have attracted attention as an incoherent light source that is required in the field of image projection such as laser displays.

A conventional SLD will be described as one of conventional semiconductor light-emitting elements.

As shown in FIG. 20, in a conventional SLD 900, a semiconductor stacked film 920 is formed on a substrate 910, and a current injection region 925 formed in the semiconductor stacked film 920 by zinc (Zn) diffusion functions as an optical waveguide. This optical waveguide extends in the longitudinal direction of the substrate 910 so as to be tilted at 5° to 15° (θ in the figure) with respect to the end facet of the optical waveguide, thereby reducing mode reflectance (see, e.g., Gerald A. Alphose, Dean B. Gibert, M. G. Harvey, and Michael Ettenberg, IEEE Journal of Quantum Electronics, 1988, Vol. 24, No. 12, page 2454). This SLD has substantially the same structure as the LD using lase FP mode oscillation, except that the optical waveguide is tilted.

### SUMMARY

Improved luminous efficiency of the light source is required for the conventional semiconductor light-emitting elements such as LEDs, LDs, and SLDs in order to reduce power consumption of apparatuses in which the semiconductor light-emitting elements are installed. While the conventional LEDs can efficiently produce spontaneous emission light in the light-emitting layer, light extraction efficiency to the outside in not enough high. This is because the light is emitted in a random direction and is reflected by the interface between the semiconductor and the outside due to the difference in refractive index. The conventional SLDs, LDs, etc. can efficiently emit light to the outside by stimulated emission light. However, since inverted carrier distribution is required to cause stimulated emission, the conventional SLDs, LDs, etc. cannot make the stimulated emission dominant as their light output unless a current (threshold current) having a fixed value or more is injected into the semiconductor light-emitting element. That is, power corresponding to the product of the threshold current and the threshold voltage (the voltage that is applied to the element to achieve the threshold current) is used to emit spontaneous emission light. This spontaneous emission light is not effectively used in the conventional SLDs and LDs, which leads to ineffective power consumption. Even when the stimulated emission is dominant, a certain amount of spontaneous emission light is produced in order to maintain the stimulated emission. Accordingly, if this spontaneous emission light is not used as light output, the power corresponding to the product of the threshold current and the threshold voltage results in ineffective power consumption, and there are limitations to improve wall-plug efficiency (conversion efficiency of light output energy from supplied consumed power per unit time) of the SLDs and the LDs.

The present invention was developed in view of the above problems, and it is an object of the present invention to provide a semiconductor light-emitting element capable of using both spontaneous emission light and stimulated emission light and having high power conversion efficiency, and a light-emitting device using the same.

In order to achieve the above object, the present invention is configured so that the semiconductor light-emitting element includes a substrate and a semiconductor stacked film, and emits light from one of the substrate side or the semiconductor stacked film side.

Specifically, a semiconductor light-emitting element according to the present invention includes: a substrate; a semiconductor stacked film that includes a first cladding layer of a first conductivity type formed on the substrate, a light-emitting layer formed on the first cladding layer, and a second cladding layer of a second conductivity type formed on the light-emitting layer, and that has an optical waveguide; a first electrode formed so as to be electrically connected to the first cladding layer; and a second electrode formed so as to be electrically connected to the second cladding layer, wherein the light-emitting layer generates guided light that is guided in the optical waveguide, and non-guided light that is not guided in the optical waveguide, and the non-guided light is emitted from one of the substrate side and the semiconductor stacked layer side to outside.

According to the semiconductor light-emitting element of the present invention, the non-guided light can be effectively used as light output, and power conversion efficiency can be improved.

In the semiconductor light-emitting element of the present invention, it is preferable that the second electrode include a transparent electrode comprised of a material that is transparent to the guided light and the non-guided light.

In this case, the second electrode may include a non-transparent electrode formed on a region of the transparent electrode other than the optical waveguide, and comprised of a material that is not transparent to the guided light and the non-guided light.

It is preferable that the semiconductor light-emitting element of the prevent invention further include: a reflecting portion formed below the light-emitting layer and configured to reflect the non-guided light.

In this case, it is preferable that the reflecting portion include a reflecting film comprised of a metal and formed on a surface of the substrate which is located on an opposite side from a surface on which the semiconductor stacked film is formed.

The reflecting portion may include a film formed on the substrate and comprised of a material having a different refractive index from that of the semiconductor stacked film.

The reflecting portion may include a recess formed in an upper part of the substrate.

In the semiconductor light-emitting element of the present invention, it is preferable that the substrate be comprised of a material that is transparent to the guided light and the non-guided light.

In this case, it is preferable that the second electrode be comprised of a material that reflects the non-guided light.

In this case, the first electrode may include a non-transparent electrode comprised of a material that is not transparent to the guided light and the non-guided light, and the non-transparent electrode may have an opening below the optical waveguide.

Moreover, in this case, it is preferable that the substrate include a concavo-convex portion having a one-dimensional period or a two-dimensional period on its surface that is located on an opposite side from a surface on which the semiconductor stacked film is formed.

In the semiconductor light-emitting element of the present invention, it is preferable that an end facet of the optical waveguide be tilted with respect to a direction perpendicular to a surface of the substrate.

A first light-emitting device according to the present invention includes: the semiconductor light-emitting element; and a package configured to hold the semiconductor light-emitting element, wherein the semiconductor light-emitting element is held such that its surface on the substrate side contacts the package, and the guided light and the non-guided light which are emitted from the semiconductor light-emitting element are emitted from an upper side of the package to the outside.

According to the first light-emitting device of the present invention, since the guided light and the non-guided light which are emitted from the semiconductor light-emitting element are emitted from the upper side of the package to the outside, both the guided light and the non-guided light can be used, and power conversion efficiency can be improved.

A second light-emitting device according to the present invention includes: the semiconductor light-emitting element; and a package configured to hold the semiconductor light-emitting element, wherein the semiconductor light-emitting element is held such that its surface on the semiconductor stacked film side contacts the package, and the guided light and the non-guided light which are emitted from the semiconductor light-emitting element are emitted from an upper side of the package to the outside.

According to the second light-emitting device of the present invention, since the guided light and the non-guided light which are emitted from the semiconductor light-emitting element are emitted from the upper side of the package to the outside, both the guided light and the non-guided light can be used, and power conversion efficiency can be improved.

In the first light-emitting device and the second light-emitting device of the present invention, it is preferable that the package have a recessed shape having a bottom surface and a sidewall surface, and the sidewall surface be tilted so as to form an obtuse angle with the bottom surface, and be configured to reflect the guided light.

It is preferable that the first light-emitting device and the second light-emitting device further include: a member provided over the package and including a phosphor.

With this configuration, since a part or all of the light emitted from the semiconductor light-emitting element can be converted in wavelength by the phosphor, the wavelength of the light that is emitted from the light-emitting device can be designed as desired.

It is preferable that the first light-emitting device and the second light-emitting device of the present invention be configured to be selectable between a first operation of emitting the guided light and the non-guided light and a second operation of emitting only the non-guided light.

With this configuration, the light-emitting device of the present invention can be efficiently used according to the application.

In this case, it is preferable that the first operation be selected when an amount of current flowing in the semiconductor light-emitting element is larger than a threshold current, and the second operation be selected when the amount of current flowing in the semiconductor light-emitting element is smaller than the threshold current.

As described above, the semiconductor light-emitting element and the light-emitting device according to the present invention can use both spontaneous emission light and stimulated emission light, and can improve power conversion efficiency.

### BRIEF DESCRIPTION OF THE DRAWINGS

FIGS. 1A-1C show a semiconductor light-emitting element according to a first embodiment, where FIG. 1A is a plan view, FIG. 1B is a cross-sectional view taken along line Ib-Ib in FIG. 1A, and FIG. 1C is a cross-sectional view taken along line Ic-Ic in FIG. 1A, and FIG. 1D is a cross-sectional view showing a light-emitting device according to the first embodiment.

FIGS. 2A-2F are cross-sectional views sequentially illustrating a manufacturing method of the semiconductor light-emitting element according to the first embodiment.

FIGS. 3A-3B show operation of the semiconductor light-emitting element according to the first embodiment, where FIG. 3A is a plan view, FIG. 3B is a cross-sectional view taken along line IIIb-IIIb in FIG. 3A, and FIG. 3C is a cross-sectional view showing operation of the light-emitting device according to the first embodiment.

FIG. 4 is a graph showing characteristics of the semiconductor light-emitting element according to the first embodiment.

FIGS. 5A-5B show a semiconductor light-emitting element according to a first modification of the first embodiment, where FIG. 5A is a plan view, and FIG. 5B is a cross-sectional view taken along line Vb-Vb in FIG. 5A.

FIGS. 6A-6B show operation of the semiconductor light-emitting element according to the first modification of the first embodiment, where FIG. 6A is a plan view, and FIG. 6B is a cross-sectional view taken along line VIb-VIb in FIG. 6A.

FIG. 7 is a graph showing characteristics of the semiconductor light-emitting element according to the first modification of the first embodiment.

FIG. 8A-8B show a semiconductor light-emitting element according to a second modification of the first embodiment, where FIG. 8A is a plan view, and FIG. 8B is a cross-sectional view taken along line VIIIb-VIIIb in FIG. 8A.

FIGS. 9A-9B show operation of the semiconductor light-emitting element concerning the second modification of the first embodiment, where FIG. 9A is a plan view, and FIG. 9B is a cross-sectional view taken along line IXb-IXb in FIG. 9A.

FIGS. 10A-10C show a semiconductor light-emitting element according to a second embodiment, where FIG. 10A is a plan view, FIG. 10B is a cross-sectional view taken along line Xb-Xb in FIG. 10A, and FIG. 10C is a bottom view.

FIG. 11A is a cross-sectional view taken along line XIa-XIa of FIG. 10A, showing a mounting form of the semiconductor light-emitting element according to the second embodiment, and FIG. 11B is a cross-sectional view showing a light-emitting device according to the second embodiment.

FIGS. 12A-12B show operation of the semiconductor light-emitting element according to the second embodiment, where FIG. 12A is a cross-sectional view showing the same section as FIG. 11A, FIG. 12B is a cross-sectional view showing the same section as FIG. 10B, and FIG. 12C is a cross-sectional view showing operation of the light-emitting device according to the second embodiment.

FIGS. 13A-13C show mounting forms of semiconductor light-emitting elements according to modifications of the second embodiment, where FIG. 13A is a cross-sectional view of a first modification, FIG. 13B is a cross-sectional view of a second modification, and FIG. 13C is a bottom view of the second modification.

FIG. 14 is a cross-sectional view showing a light-emitting device according to a third embodiment.

FIG. 15 is a cross-sectional view showing operation of the light-emitting device according to the third embodiment.

FIGS. 16A-16C are diagrams and a graph showing an application example of the light-emitting device according to the third embodiment.

FIGS. 17A-17C show a semiconductor light-emitting element according to a fourth embodiment, where FIG. 17A is a plan view, FIG. 17B is a cross-sectional view taken along line XVIIb-XVIIb in FIG. 17A, and FIG. 17C is a bottom view.

FIG. 18A is a cross-sectional view taken along XVIIIa-XVIIIa in FIG. 17A, showing a mounting form of the semiconductor light-emitting element according to the fourth embodiment, and FIG. 18B is a cross-sectional view showing a light-emitting device according to the fourth embodiment.

FIG. 19A is a cross-sectional view showing operation of the semiconductor light-emitting element according to the fourth embodiment, and FIG. 19B is a cross-sectional view showing operation of the light-emitting device according to the fourth embodiment.

FIG. 20 is a perspective view showing a conventional semiconductor light-emitting element.

### DETAILED DESCRIPTION

### First Embodiment

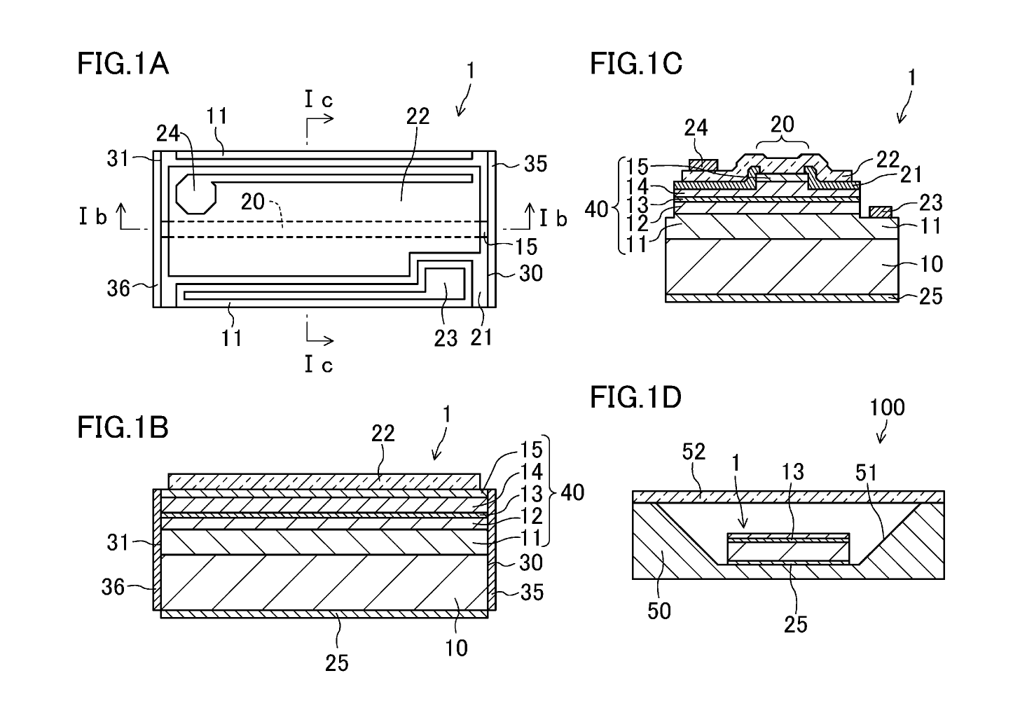

A semiconductor light-emitting element according to a first embodiment will be described with reference to FIGS. 1A-1C. A semiconductor light-emitting element 1 according to the present embodiment is a semiconductor light-emitting element that is comprised of a nitride semiconductor and emits light in the range from ultraviolet to blue with an emission wavelength of 380 nm to 490 nm, and that has an optical waveguide functioning as a laser diode (LD) in a part of the semiconductor light-emitting element. A semiconductor light-emitting element having an emission wavelength close to 405 nm is described in the present embodiment. As shown in FIGS. 1A-1C, a nitride semiconductor stacked film 40 is formed on a substrate 10 comprised of sapphire. The nitride semiconductor stacked film 40 is a stacked film in which, e.g., a lower contact layer 11 comprised of N-type gallium nitride (GaN), a lower cladding layer (first cladding layer) 12 comprised of N-type aluminum gallium nitride (Al_{0.05}Ga_{0.95}N), a light-emitting layer 13 as an active layer, an upper cladding layer (second cladding layer) 14 as a P-type AlGaN superlattice cladding layer, and an upper contact layer 15 comprised of P-type GaN are sequentially stacked. The lower contact layer 11 has a thickness of about 1 μm, and has been doped with Si so as to have a silicon (Si) concentration of about 1×10¹⁸ cm⁻³. The lower cladding layer 12 has a thickness of about 1.5 μm, and has been doped with Si so as to have an Si concentration of about 5×10¹⁷ cm⁻³. The light-emitting layer 13 includes an N-side light guide layer having a thickness of about 0.1 um and composed of undoped GaN, an indium gallium nitride (InGaN) multiple quantum well active layer, a P-side light guide layer having a thickness of about 0.1 μm and comprised of undoped GaN, and an electron blocking layer having a thickness of about 10 nm and comprised of P-type Al_{0.2}Ga_{0.8}N doped with magnesium (Mg) so as to have an Mg concentration of about 1×10¹⁹ cm⁻³. The InGaN multiple quantum well active layer has a triple quantum well structure that is formed by an undoped InGaN well layer having a thickness of about 3 nm, and an undoped In_{0.02}Ga_{0.98}N bather layer having a thickness of about 7 nm The Indium composition of the well layer is controlled so that the emission wavelength is about 405 nm. The upper cladding layer 14 has a superlattice structure in which the total thickness of a P-type Al_{0.1}Ga_{0.9}N film having a thickness of about 2 nm and a P-type GaN film having a thickness of about 2 nm is about 0.5 μm, and has been doped with Mg so as to have a Mg concentration of about 1×10²⁰ cm⁻³ The upper cladding layer 14 has a ridge stripe portion, and the optical waveguide 20 is formed by the ridge stripe portion. The direction in which the optical waveguide 20 extends is the <1-100> direction of the crystal axis of the stacked GaN film. The above thickness of the upper cladding layer 14 is the thickness of the portion where the ridge stripe portion is formed, and the thickness of the portion where the ridge stripe portion is not formed is 0.1 μm. The width of the lower end of the ridge stripe portion is 2 μm, and the width of the upper end of the ridge stripe portion is 1.4 μm. The upper contact layer 15 has a thickness of about 20 nm, and has been doped with Mg so as to have an Mg concentration of about 1×10²⁰ cm⁻³. The upper contact layer 15 is formed only on the top surface of the ridge stripe portion of the upper cladding layer 14.

A current blocking layer 21 comprised of silicon oxide (SiO₂) is formed on the upper cladding layer 14. The current blocking layer 21 has an opening on the ridge stripe portion. A transparent electrode (part of the second electrode) 22 is formed on the current blocking layer 21 and the upper contact layer 15. The transparent electrode 22 is comprised of indium tin oxide (ITO) that is transparent to guided light and non-guided light described below. An N-side electrode (first electrode) 23 is formed the lower contact layer 11, and a P-side electrode (part of the second electrode) 24 is formed on a region of the transparent electrode 22 other than the optical waveguide 20. The P-side electrode 24 is comprised of a material that is not transparent to guided light and non-guided light described below. A reflecting film 25 as the reflecting portion is formed on the surface of the substrate 10 which is located on the opposite side from the surface on which the nitride semiconductor stacked film 40 is formed. The reflecting film 25 is composed of, e.g., an alloy containing aluminum (Al), platinum (Pt), and gold (Au).

Although not shown in the figure, a chip of the semiconductor light-emitting element 1 is formed by performing cleavage along a (1-100) plane of the stacked GaN film as a cleavage plane. The chip size including a bonding pad region is such that the chip width is about 150 μm and the chip length is about 800 μm. In the semiconductor light-emitting element 1, a first protective film 35 having reflectance of about 10% is formed on a front end facet 30 configured to emit guided light, and a second protective film 36 having reflectance of about 95% is formed as an end-facet reflecting film on a rear end facet 31 configured to reflect the guided light back to the optical waveguide.

A light-emitting device according to the first embodiment will be described below with reference to FIG. 1D. The semiconductor light-emitting element 1 is shown in a simplified manner in FIG. 1D. As shown in FIG. 1D, in a light-emitting device 100 according to the present embodiment, the semiconductor light-emitting element 1 according to the present embodiment is mounted in a package 50 with the reflecting film 25 interposed therebetween. The package 50 has a concave shape opening upward. The inside of the package 50 has a bottom surface holding the semiconductor light-emitting element 1 thereon, and a sidewall surface connecting the bottom surface to an upper surface of the package 50. The sidewall surface is a tilted surface forming an obtuse angle with the bottom surface, and the sidewall surface is a reflecting surface 51 capable of reflecting light. A metal wire (not shown) is buried in the package 50, and the metal wire is connected to the P-side electrode 24 and the N-side electrode 23 of the semiconductor light-emitting element 1 by, e.g., a metal thin wire (not shown), so that electric power can be supplied from the outside of the package 50 to the semiconductor light-emitting element 1. A cover glass 52 is provided in the opening on the upper side (light-emission side) of the package 50 so as to seal the inside of the package 50.

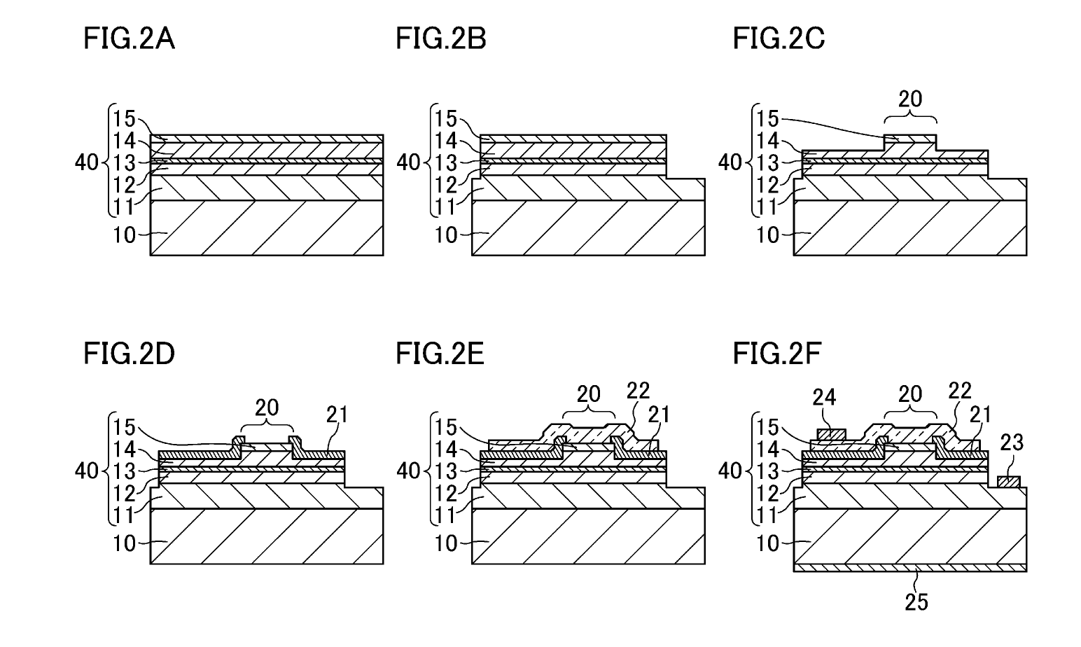

A manufacturing method of the semiconductor light-emitting element according to the first embodiment will be described with reference to FIGS. 2A-2F.

As shown in FIG. 2A, a nitride semiconductor stacked film 40 is formed on a substrate 10 comprised of sapphire by, e.g., a metal organic chemical vapor deposition (MOCVD) method. Specifically, a lower contact layer 11 comprised of N-type GaN, a lower cladding layer 12 comprised of N-type Al_{0.05}Ga_{0.95}N, a light-emitting layer 13, an upper cladding layer 14 as a P-type AlGaN superlattice cladding layer, and an upper contact layer 15 comprised of P-type GaN are sequentially stacked.

Then, as shown in FIG. 2B, the lower cladding layer 12, the light-emitting layer 13, the upper cladding layer 14, and the upper contact layer 15 are partially subjected to, e.g., dry etching and wet etching to expose a part of the lower contact layer 11.

Thereafter, as shown in FIG. 2C, the upper cladding layer 14 and the upper contact layer 15 are subjected to etching to form in the upper cladding layer 14 a ridge stripe portion that forms an optical waveguide 20.

Subsequently, as shown in FIG. 2D, a current blocking layer 21 comprised of SiO₂ is formed on the upper cladding layer 14 and the upper contact layer 15, and the current blocking layer 21 formed on the upper contact layer 15 is removed by etching.

Then, as shown in FIG. 2E, a transparent electrode 22 comprised of ITO is formed on the upper contact layer 15 and the current blocking layer 21.

Next, as shown in FIG. 2F, an N-side electrode 23 is formed on the lower contact layer 12 exposed in FIG. 2B, and a P-side electrode 24 is formed on a region of the transparent electrode 22 other than the optical waveguide 20. A reflecting film 25 comprising of an alloy containing Al, Pt, and Au is formed on the surface of the substrate 10 which is located on the opposite side from the surface on which the nitride semiconductor stacked layer 40 is formed. The semiconductor light-emitting element 1 can be formed in this manner.

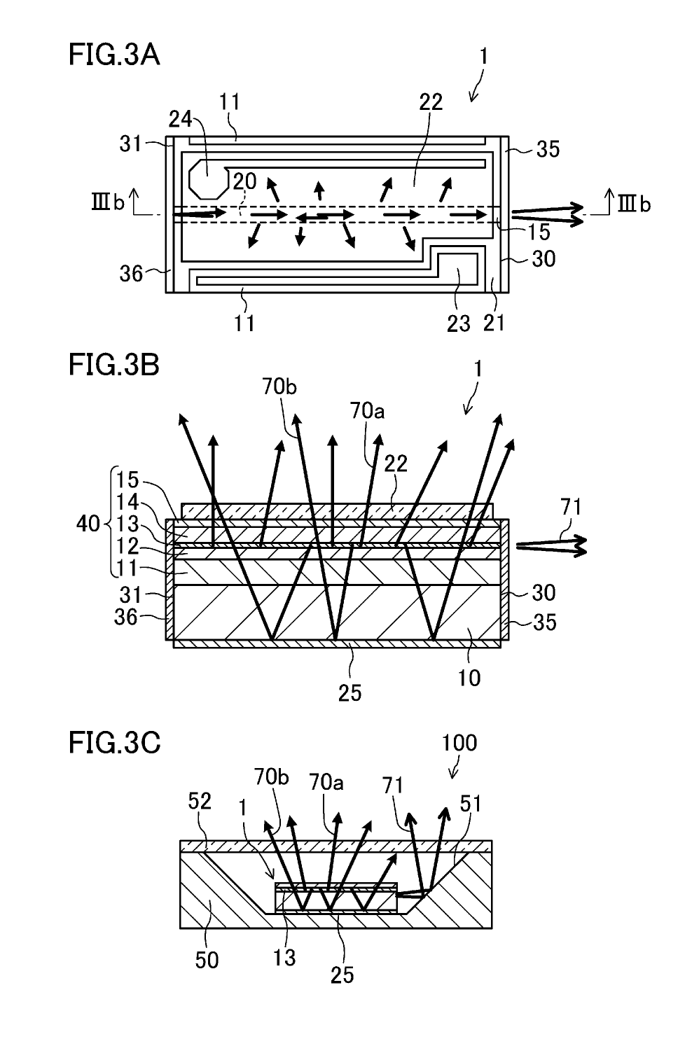

Operation of the semiconductor light-emitting element according to the first embodiment will be described with reference to FIGS. 3A-3B. As shown in FIGS. 3A-3B, electrons and holes are injected from the N-side electrode 23 and the P-side electrode 24 into the light-emitting layer (active layer) 13. Laser oscillation is caused at a threshold current value or higher, and guided light 71 mainly containing stimulated emission light is emitted from the front end facet 30. On the other hand, non-guided light 70a mainly containing spontaneous emission light and emitted upward of the optical waveguide 20 is emitted from a region above the optical waveguide 20 (the semiconductor stacked film 40 side) to the outside of the semiconductor light-emitting element 1. Non-guided light 70b emitted downward of the optical waveguide 20 is reflected by the reflecting film 25, and is emitted from the region above the optical waveguide 20 to the outside of the semiconductor light-emitting element 1. In this case, since the P-side electrode 24 is not placed on the optical waveguide 20, the emission of the non-guided light 70a, 70b is not blocked.

Operation of the light-emitting device according to the first embodiment will be described with reference to FIG. 3C. The semiconductor light-emitting element 1 is shown in a simplified manner in FIG. 3C. As shown in FIG. 3C, the guided light 71 is emitted from the front end facet 30 of the semiconductor light-emitting element 1. The guided light 71 thus emitted is reflected by the reflecting surface 51 of the package 50, and is emitted to the outside of the package 50 through the cover glass 52. On the other hand, the non-guided light 70a, 70b emitted from the region above the optical waveguide 20 of the semiconductor light-emitting element 1 is also emitted to the outside of the package 50 through the cover glass 52. Accordingly, the stimulated emission light mainly containing the guided light 71 and the spontaneous emission light mainly containing the non-guided light 70a, 70b are both emitted from the same surface side (upper side) of the package 50 through the cover glass 52, and can be used as light output.

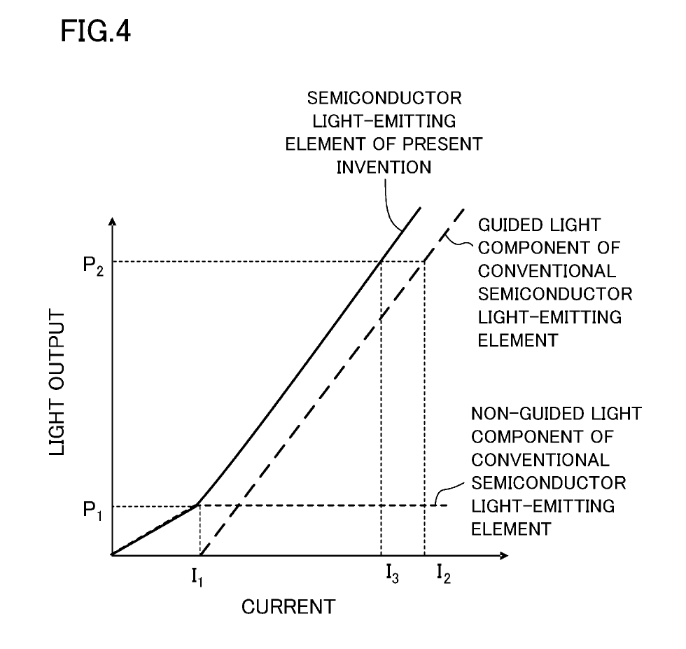

Characteristics of the semiconductor light-emitting element according to the first embodiment will be described with reference to FIG. 4. As shown in FIG. 4, since the light output of the semiconductor light-emitting element of the present embodiment is increased by P₁ by the non-guided light component, as compared to the conventional semiconductor light-emitting element, an operating current that is applied to obtain light output P₂ can be reduced from I₂ to I₃.

According to the semiconductor light-emitting element and the light-emitting device of the first embodiment, both spontaneous emission light and stimulated emission light can be used, and power conversion efficiency as wall-plug efficiency can be improved.

### First Modification of First Embodiment

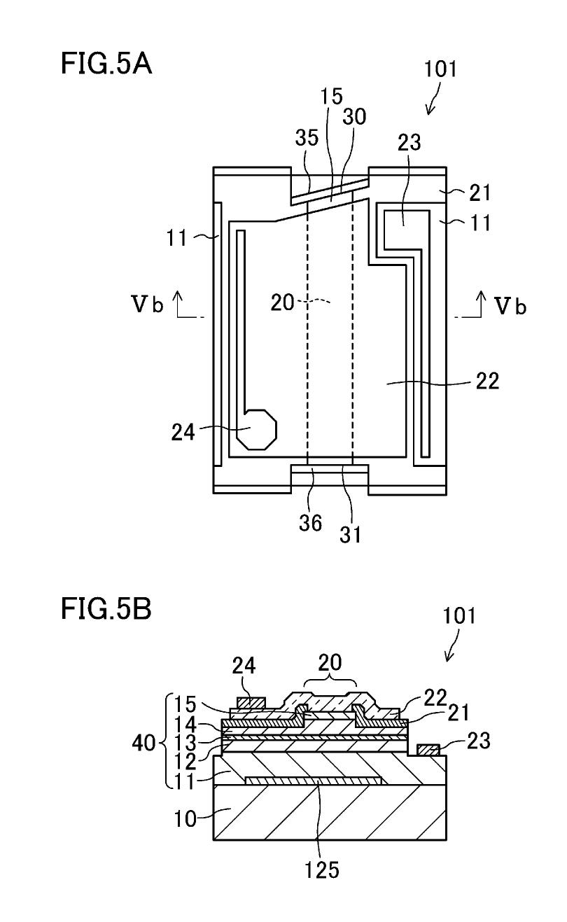

A semiconductor light-emitting element according to a first modification of the first embodiment will be described with reference to FIGS. 5A-5B. In this modification, description of the same portions as those of the first embodiment is omitted, and only the portions different from those of the first embodiment will be described. As shown in FIGS. 5A-5B, a semiconductor light-emitting element 101 according to this modification is an element having an optical waveguide functioning as a super luminescent diode (SLD) in a part of the semiconductor light-emitting element, and is different from the first embodiment in the formation position and composition of the reflecting portion formed below the light-emitting layer 13. Moreover, the first modification is different from the first embodiment in that the front end facet 30 is tilted about 10° with respect to the lateral direction of the optical waveguide 20. The rear end facet 31 is perpendicular to the longitudinal direction of the optical waveguide 20.

Specifically, the semiconductor light-emitting element 101 according to this modification has a selective growth mask 125 formed on a part of the substrate 10. The selective growth mask 125 is formed in a stripe shape with a width of about 10 μm, and is comprised of SiO₂. Accordingly, when forming the lower contact layer 11 over the substrate 10, the lower contact layer 11 is selectively grown from a region of the substrate 10 which is exposed from the selective growth mask 125. The lower contact layer 11 is thus formed from both sides in the lateral direction of the selective growth mask 125 toward the central portion thereof so as to cover the selective growth mask 125. Forming a GaN film having a different crystal structure on the sapphire substrate 10 increases threading dislocation density of the GaN film, and reduces internal quantum efficiency. In this modification, the selective growth mask 125 is formed as described above. This can reduce threading dislocation density of the GaN film such as the lower contact layer 11 formed on the sapphire substrate 10, and can improve internal quantum efficiency of the light-emitting layer 13. The joint portion of the selectively grown GaN film (the central portion in the lateral direction of the selective growth mask 125) has high threading dislocation density, and thus reduces the internal quantum efficiency of the light-emitting layer 13. Accordingly, the selective growth mask 125 is formed so that the central portion in the lateral direction of the optical waveguide 20 as a light-emitting region is shifted from the central portion in the lateral direction of the selective growth mask 125 by about 3 μm. Since the refractive index of the selective growth mask 125 comprised of SiO₂ is different from that of the lower contact portion 11 comprised of GaN, light is reflected by Fresnel reflection or total reflection by the interface between the selective growth mask 125 and the lower contact layer 11. That is, the selective growth mask 125 functions as the reflecting portion. Accordingly, in this modification, a reflecting film may not be formed on the rear surface of the substrate 10. However, the reflecting film may be formed on the rear surface of the substrate 10 as necessary.

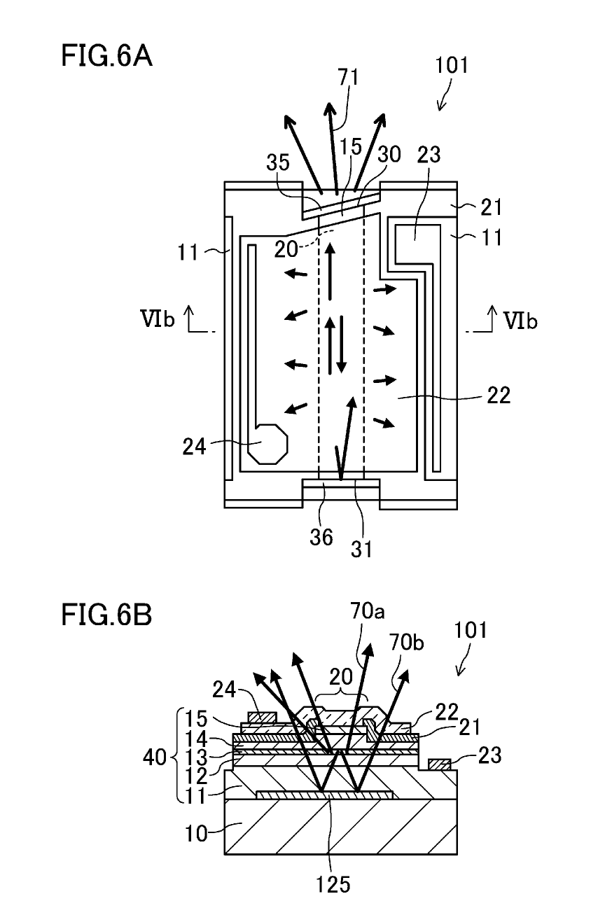

Operation of the semiconductor light-emitting element according to the first modification of the first embodiment will be described with reference to FIGS. 6A-6B. As shown in FIGS. 6A-6B, in the present modification, the front end facet 30 is tilted by about 10° with respect to the lateral direction of the optical waveguide 20. Accordingly, in the case where the guided light 71 is reflected by the front end facet 30, the mode reflectance back to the optical waveguide 20 decreases to about 10⁻³%. This suppresses laser oscillation by end facet reflection (FP mode laser oscillation), whereby SLD operation (stimulated emission operation without laser oscillation) can be implemented. The first protective film 35 is formed so as to have reflectance (Fresnel reflectance) of about 0.5%, which further reduces mode reflectance. On the other hand, since the rear end facet 31 having the second protective film 36 formed thereon extends perpendicularly to the longitudinal direction of the optical waveguide 20, the rear end facet 31 has reflectance of about 95% as in the first embodiment. Thus, the guided light propagating toward the rear end facet 31 is reflected by the rear end facet 31. Accordingly, an effective amplification length can be increased to twice the chip length without causing reduction in carrier density by an increase in chip length.

This configuration not only suppresses laser oscillation by low reflection at the front end facet 30, but also suppresses gain saturation at the front end facet 30, and increases the amplification length by high reflection at the rear end facet 31, thereby improving external quantum efficiency. Accordingly, SLD operation can be implemented even with light output as high as about 200 mW.

The non-guided light 70a, 70b is emitted upward and downward from the light-emitting layer 13, respectively. The non-guided light 70b emitted downward from the light-emitting layer 13 is reflected upward by Fresnel reflection or total reflection by the interface between the lower contact layer 11 and the selective growth mask 125. Accordingly, the non-guided light 70a, 70b is emitted from a region above the optical waveguide 20 to the outside of the semiconductor light-emitting element 101.

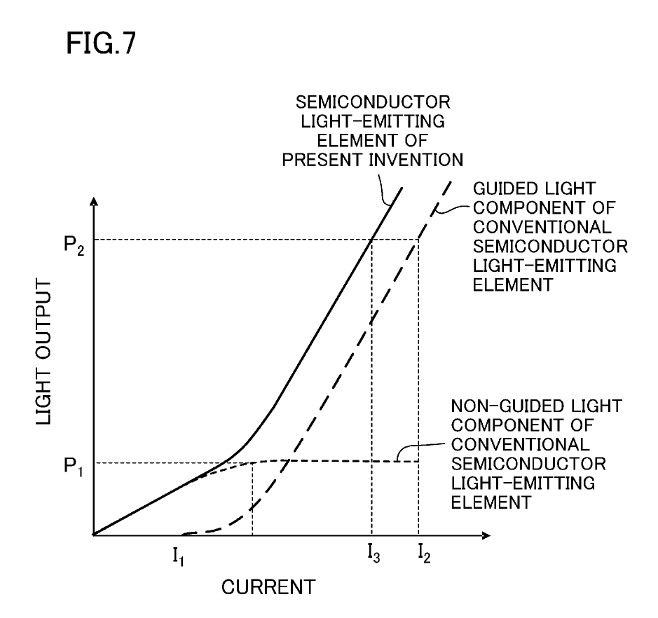

Characteristics of the semiconductor light-emitting element according to the first modification of the first embodiment will be described with reference to FIG. 7. As shown in FIG. 7, unlike the LD of the first embodiment, an increase in light output of the stimulated emission light becomes gradual at the stage where the stimulated emission light becomes dominant. However, essentially as in the first embodiment, the non-guided light mainly containing spontaneous emission light can be used as light output. Accordingly, in the semiconductor light-emitting element of this modification, the operating current with the light output P₂ can be reduced from I₂ to I₃, as compared to the conventional semiconductor light-emitting element.

The semiconductor light-emitting element according to the first modification of the first embodiment can use both spontaneous emission light and stimulated emission light, and can improve power conversion efficiency as wall-plug efficiency.

### Second Modification of First Embodiment

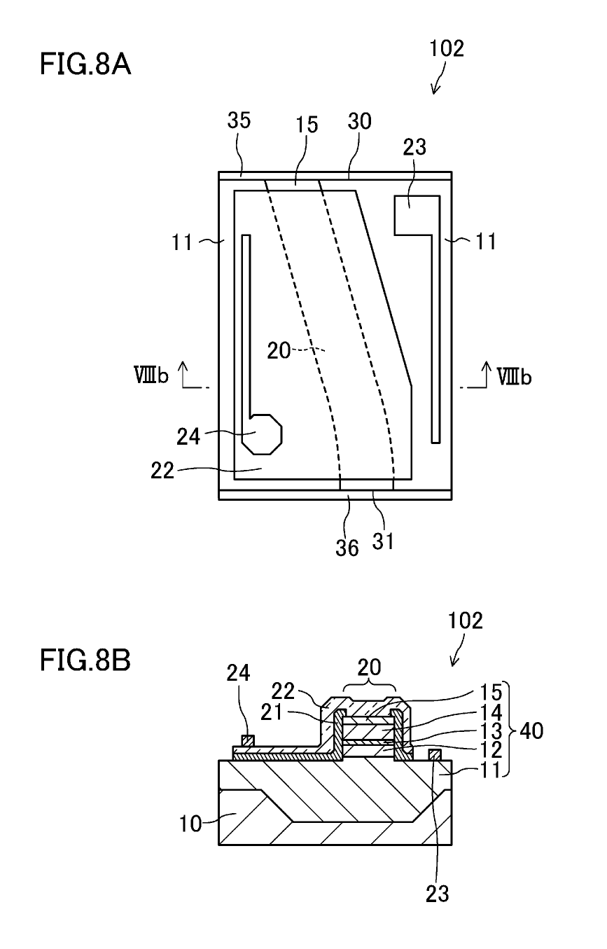

A semiconductor light-emitting element according to a second modification of the first embodiment will be described with reference to FIGS. 8A-8B. In the modification, description of the same portions as those of the first embodiment is omitted, and only the portions different from those of the first embodiment will be described. As shown in FIGS. 8A-8B, a semiconductor light-emitting element 102 according to this modification is an SLD, and the shape of the reflecting portion formed below the light-emitting layer 13 is different from the first embodiment. The second modification of the first embodiment is also different from the first embodiment in that the optical waveguide 20 is tilted with respect to the direction perpendicular to the front end facet 30.

Specifically, in the semiconductor light-emitting element 102 of this modification, a recess is formed in the upper part of the substrate 10 as the reflecting portion. This recess is formed in a stripe shape along the guiding direction of the optical waveguide 20. The recess has a depth of about 1 μm and a width of about 10 μm at the bottom. Growing the lower contact layer 11 on the substrate 10 made of sapphire different from the material of the lower contact layer 11 commonly causes threading dislocation in the lower contact layer 11. However, since the lower contact layer 11 is formed on the recess in this modification, the threading dislocation density can be reduced and the internal quantum efficiency of the active layer can be improved, as in the first modification of the first embodiment. As in the first modification of the first embodiment, the central portion in the lateral direction of the optical waveguide 20 is shifted from the central portion in the lateral direction of the bottom surface of the recess by about 3 μm.

In the semiconductor light-emitting element 102 of this modification, the optical waveguide 20 is tilted by about 10° with respect to the direction perpendicular to the front end facet 30 and extends perpendicularly to the rear end facet 31 in order to carry out SLD operation. The length along which the optical waveguide 20 is tilted is about 600 μm from the front end facet 30. The optical wavelength 20 is curved with a curvature of about 1,000 μm so as to extend perpendicularly to the rear end facet 31.

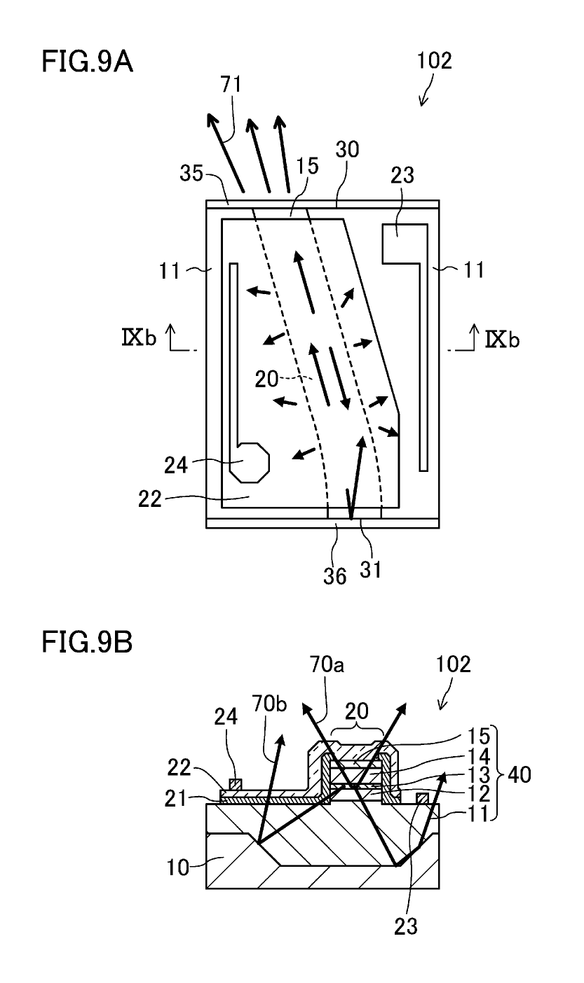

Operation of the semiconductor light-emitting element 102 according to the second modification of the first embodiment will be described with reference to FIGS. 9A-9B. As shown in FIGS. 9A-9B, since the front end facet 30 is tilted with respect to the direction perpendicular to the optical waveguide 20, the mode reflectance decreases to about 10⁻³%. This suppresses laser oscillation by end facet reflection, whereby SLD operation can be implemented. On the other hand, since the rear end facet 31 extends perpendicularly to the optical waveguide 20, the mode reflectance of the rear end facet 31 is about 95% as in the first embodiment. Since the joint region between the tilted portion on the front end facet 30 side of the optical waveguide 20 and the vertical portion on the rear end facet 31 side of the optical waveguide 20 has a sufficiently large curvature of 1,000 μm, propagation loss of the guided light due to the bending of the optical waveguide 20 is negligible, and luminous efficiency of the SLD is not reduced. With this configuration, SLD operation can be performed even with light output as high as about 200 mW, as in the first modification of the first embodiment.

The non-guided light 70a, 70b is emitted upward, downward, etc. of the optical waveguide 20. Of the non-guided light 70a, 70b, the non-guided light 70b emitted downward from the light-emitting layer 13 is reflected upward by Fresnel reflection and total reflection by the interface of the lower contact layer 11 and the substrate 10. Accordingly, the non-guided light 70a, 70b is emitted from a region above the optical waveguide 20 to the outside of the semiconductor light-emitting element 102. In this modification as well, a reflecting film may be formed below the substrate 10. In this case, as in the first modification of the first embodiment, the non-guided light mainly including spontaneous emission light can be used as light output, the operating current can be reduced.

The semiconductor light-emitting element according to the second modification of the first embodiment can use both spontaneous emission light and stimulated emission light, and thus can improve power conversion efficiency as wall-plug efficiency.

### Second Embodiment

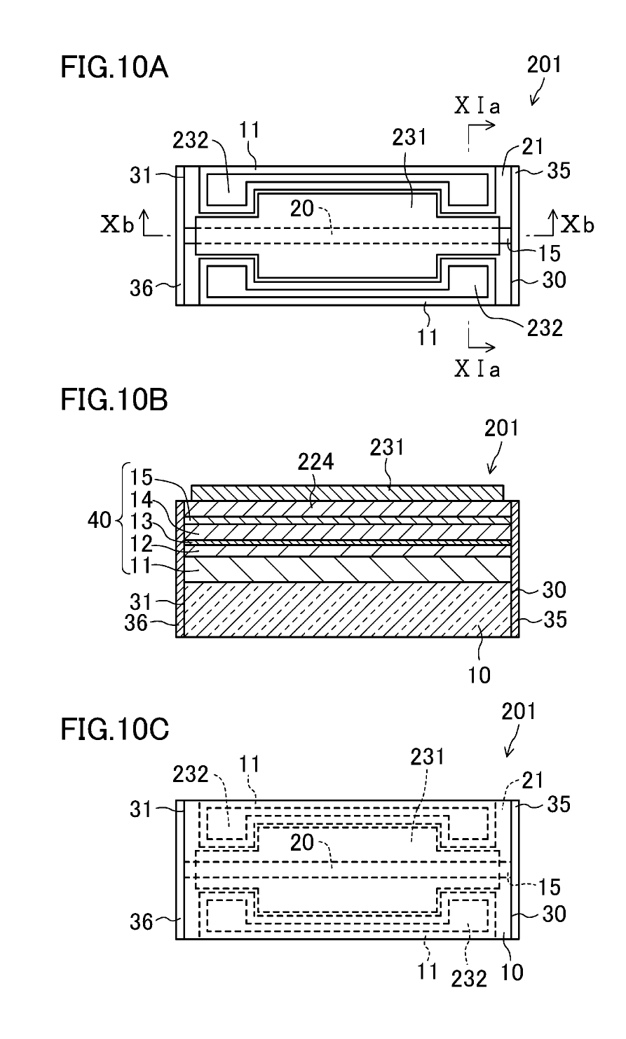

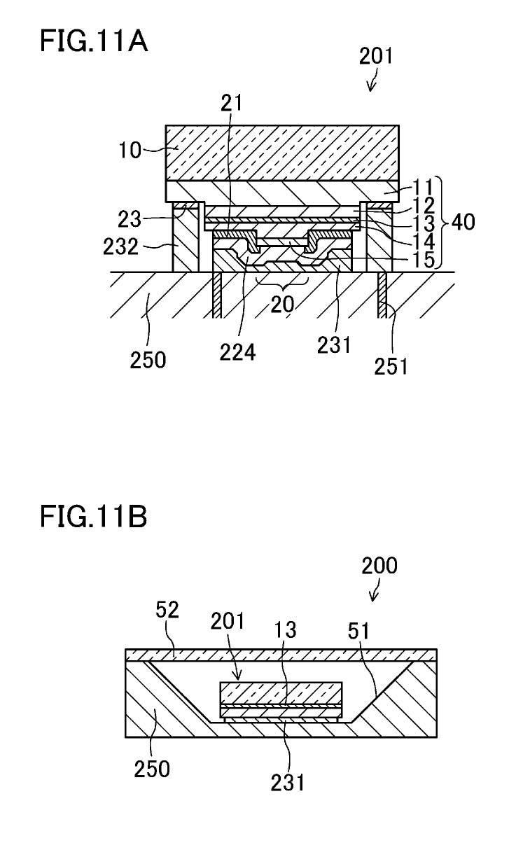

A semiconductor light-emitting element according to a second embodiment will be described with reference to FIGS. 10A-10C and 11A. In the present embodiment, description of the same portions as those of the first embodiment is omitted, and only the portions different from those of the first embodiment will be described. As shown in FIGS. 10A-10C and 11A, the semiconductor light-emitting element according to the present embodiment is an LD as in the first embodiment, but is different from the first embodiment in that the reflecting film is not formed below the substrate 10. A semiconductor light-emitting element 201 of the present embodiment is mounted on a package 250 described below such that the P-side (upper side) contacts the bottom surface of the package 250 (junction down mounting). In the present embodiment, it is preferable that the substrate 10 be transparent to guided light and non-guided light described below.

Specifically, the semiconductor light-emitting element 201 of the present embodiment has no transparent electrode as the second electrode or P-side electrode, but instead has a high reflectance P-side electrode 224. The high reflectance P-side electrode 224 is comprised of a material having high reflectance and forming an ohmic contact with P-type GaN, such as an alloy of Pd, Ag, Pt, or Au.

Since the semiconductor light-emitting element 201 of the second embodiment is mounted on the package 250 by junction down mounting, a first bump 231 comprised of Au is formed on the high reflectance P-side electrode 224 so as to obtain a flat mount surface. Moreover, a second bump 232 comprised of Au is formed on the exposed surface of the lower contact layer 11 with the N-side electrode 23 interposed therebetween. The first bump 231 and the second bump 232 allow the semiconductor light-emitting element 201 to be stably and horizontally mounted on the package 250.

A light-emitting device according to the second embodiment will be described with reference to FIGS. 11A-11B. The semiconductor light-emitting element 201 is shown in a simplified manner in FIG. 11B. As shown in FIGS. 11A-11B, the semiconductor light-emitting element 201 is mounted on the package 250 by junction down mounting. In the light-emitting device 200 of the second embodiment, via interconnects 251 as interconnects extending through the bottom surface of the package 250 are formed in the package 250. The via interconnects are connected to the first bump 231 and the second bump 232, whereby the semiconductor light-emitting element 201 can be electrically connected to the outside of the package 250. Thus, the interconnection step can be omitted.

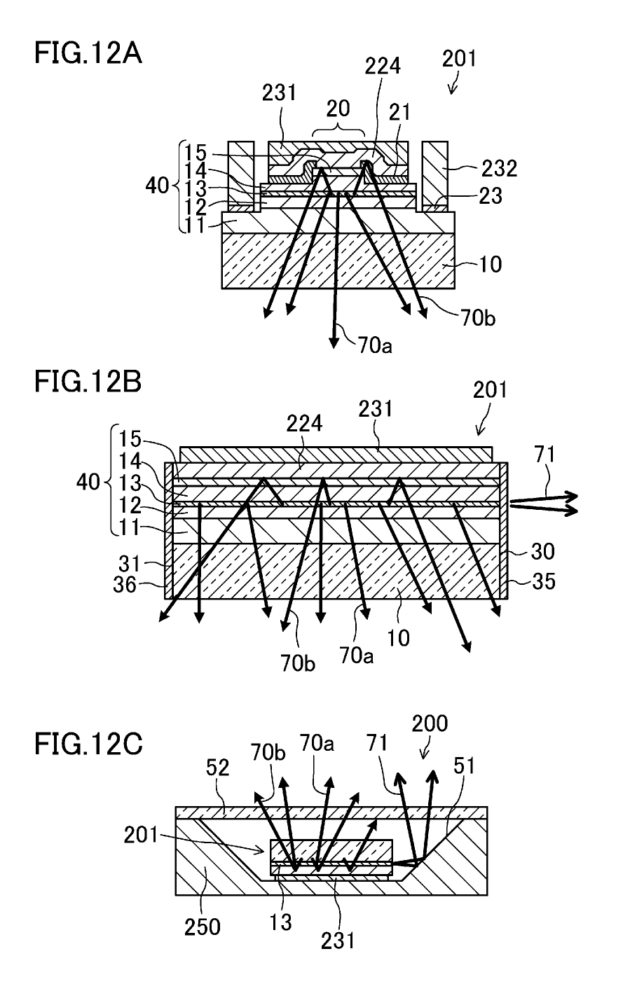

Operation of the semiconductor light-emitting element of the second embodiment will be described with reference to FIGS. 12A and 12B. As shown in FIGS. 12A and 12B, guided light 71 mainly including stimulated emission light is emitted from the front end facet 30 by laser oscillation as in the first embodiment. Non-guided light 70a mainly including spontaneous emission light is emitted from the light-emitting layer 13 toward the substrate 10 to the outside of the semiconductor light-emitting element 201, and non-guided light 70b is emitted from the light-emitting layer 13 toward the upper cladding layer 14, and is reflected toward the substrate 10 by the high reflectance P-side electrode 224 and emitted to the outside of the semiconductor light-emitting element 201. In this case, no member that blocks light such as an electrode is provided between the substrate 10 and the light-emitting layer 13, and emission of the non-guided light 70a, 70b is not blocked. Since the non-guided layer 70a, 70b together with the guided light 71 can be used as light output, luminous efficiency can be improved and an operating current can be reduced as in the first embodiment.

Operation of the light-emitting device according to the second embodiment will be described with reference to FIG. 12C. As shown in FIG. 12C, the guided light 71 emitted from the front end facet 30 of the semiconductor light-emitting element 201 is reflected by the reflecting surface 51 of the package 250, and is emitted to the outside of the package 50 through the cover glass 52. The non-guided light 70a, 70b is also emitted to the outside of the package 50 through the cover glass 52. Accordingly, both the stimulated emission light mainly included in the guided light 71 and the spontaneous emission light mainly included in the non-guided light 70a, 70b are emitted from the cover glass 52, namely from the same surface side (upper side) of the package 250, and can be used as light output.

According to the semiconductor light-emitting element and the light-emitting device of the second embodiment, both spontaneous emission light and stimulated emission light can be used, and power conversion efficiency as wall-plug efficiency can be improved.

### Each Modification of Second Embodiment

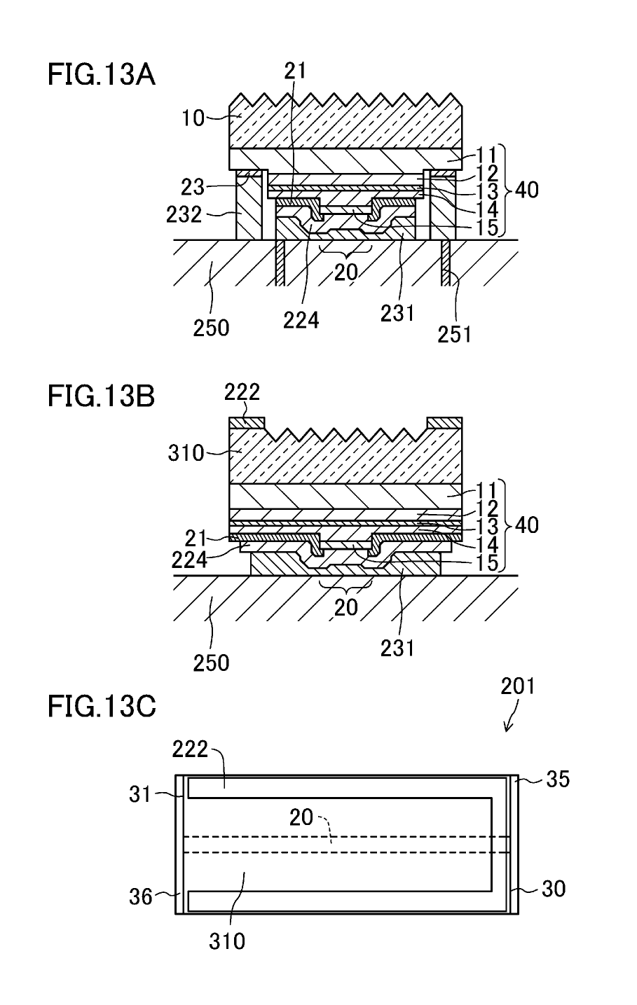

A semiconductor light-emitting element according to each modification of the second embodiment will be described with reference to FIGS. 13A-13C. As shown in FIG. 13A, in a modification of the second embodiment, a concavo-convex portion having a height of about 500 nm and a width of about 500 nm is randomly formed on the rear surface of the substrate 10 (the surface on the opposite side from the surface on which the nitride semiconductor stacked film 40 is formed). Forming the concavo-convex portion causes light scattering and diffraction, and can reduce total reflection in the substrate 10. Accordingly, light extraction efficiency of the non-guided light from the substrate 10 can be approximately three times as high as that in the case where the substrate 10 has a flat rear surface. The luminous efficiency of the semiconductor light-emitting element 201 is improved over the semiconductor light-emitting element according to the second embodiment, and the operating current can further be reduced.

The concavo-convex portion formed in the rear surface of the substrate 10 need not necessarily be randomly formed, and may be periodically formed. The periodic structure may have either a one-dimensional period (diffraction grating) or a two-dimensional period (two-dimensional photonic crystal).

In another modification of the second embodiment, as shown in FIGS. 13B and 13C, a conductive N-type GaN substrate 310 is used as a substrate. Accordingly, a non-transparent electrode 222 comprised of a metal can be provided on the rear surface of the N-type GaN substrate 310. In this case, the non-transparent electrode 222 has an opening so as not to block non-guided light emitted from the light-emitting layer 13.

The semiconductor light-emitting element according to each modification of the second embodiment can use both spontaneous emission light and stimulated emission light, and thus can improve power conversion efficiency as wall-plug efficiency.

### Third Embodiment

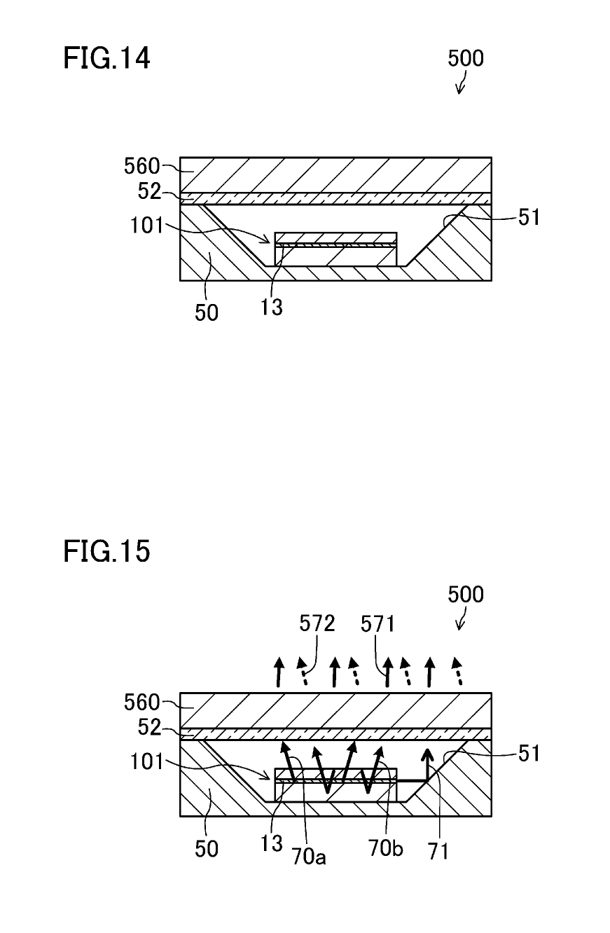

A light-emitting device according to a third embodiment will be described with reference to FIG. 14. In the present embodiment, description of the same portions as those of the first embodiment is omitted, and only the portions different from those of the first embodiment will be described. A semiconductor light-emitting element 101 used in the light-emitting device of the present embodiment is the semiconductor light-emitting element according to the first modification of the first embodiment, and particularly is a semiconductor light-emitting element having an optical waveguide functioning as an SLD that emits light having a wavelength close to 405 nm. The semiconductor light-emitting element 101 is shown in a simplified manner in FIG. 14. As shown in FIG. 14, unlike the light-emitting device of the first embodiment, a phosphor layer 560 is applied to the cover glass 52 of the package 50 in a light-emitting device 500 of the present embodiment. The phosphor layer 560 includes three kinds of phosphor, namely a phosphor emitting red (R) fluorescence having a wavelength of 590 mm to 680 mm, a phosphor emitting green (G) fluorescence having a wavelength of 500 mm to 590 mm, and a phosphor emitting blue (B) fluorescence having a wavelength of 450 mm to 500 mm. Specific examples of these three kinds of phosphor are as follows. For example, the phosphor emitting red fluorescence is (Sr, Ca)AlSiN₃:Eu, the phosphor emitting green fluorescence is β-SiAlON:Eu, and the phosphor emitting blue fluorescence is BaMgAl₁₀O₁₇:Eu.

Operation of the light-emitting device according to the third embodiment will be described with reference to FIG. 15. As shown in FIG. 15, in the light-emitting device 500 according to the present embodiment, guided light 71 and non-guided light 70a, 70b emitted from the semiconductor light-emitting element 101 passes through the phosphor layer 560, and is output to the outside of the package 50 as exciting light 571. Part of the exciting light 571 is absorbed by the phosphor layer 560 to excite the phosphor, whereby red, green, and blue fluorescence 572 is produced from the phosphor. As a result, the light-emitting device 500 functions as a light-emitting device emitting white light.

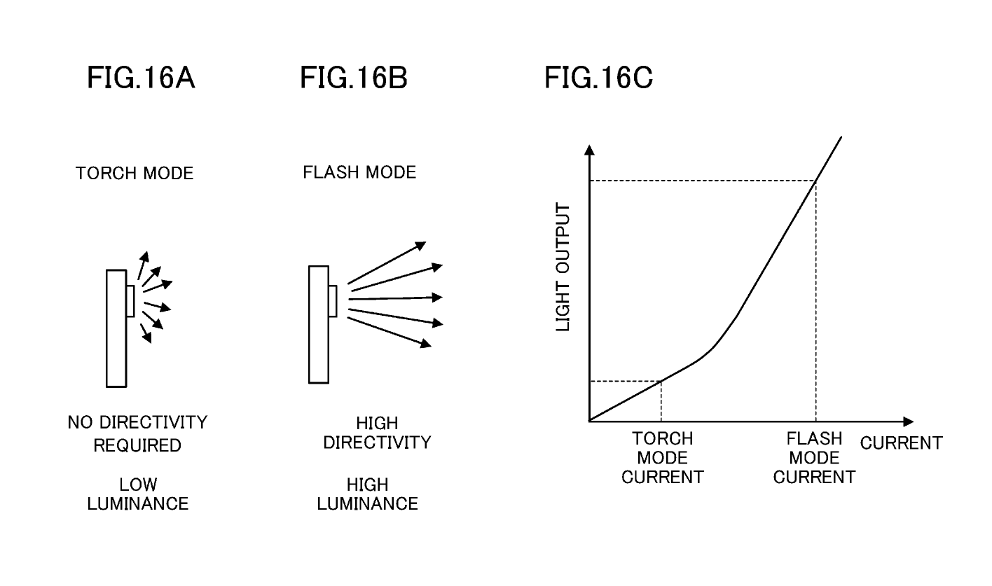

An application example of the light-emitting device of the third embodiment will be described with reference to FIGS. 16A-16C. A specific example will be described in which the light-emitting device of the present embodiment is used as a light source for flashlights of mobile phones, smart phones, etc. having a digital camera mounted thereon. This application example actively makes use of the fact that the light-emitting device of the third embodiment emits light with different characteristics based on different emission principles according to different operating currents.

First, as shown in FIGS. 16A and 16C, in the case where the operating current flowing in the semiconductor light-emitting element 101 is smaller than the threshold current and thus stimulated emission has not been started or the amount of light is small, the emitted light from the semiconductor light-emitting element 101 is mainly the spontaneous emission light. In this case, the emitted light has low directivity, and the emission angle pattern of the light emission has a broad distribution such as Lambertian distribution. That is, the white light emitted from the light-emitting device 500 has low luminance, but has low directivity, whereby a wide range can be irradiated with this white light. Accordingly, light that is emitted at such a small operating current can be used in a torch mode of a light source for flashlights.

As shown in FIGS. 16B and 16C, in the case where the operating current flowing in the semiconductor light-emitting element 101 is larger than the threshold current, and thus stimulated emission becomes dominant and the amount of light is large, the emitted light from the semiconductor light-emitting element 101 is mainly the stimulated emission light having a relatively narrow emission angle of about 10° to 20°. Accordingly, the light that is emitted from the phosphor layer 560 is mainly the white light that is emitted from a region having a relatively small area (near a region above the reflecting surface of the package). If a lens etc. is designed and placed according to the region that emits the white light, light having high luminance and a narrow emission angle, which is emitted at such a large operating current, can be used in a flash mode of a light source capable of selectively illuminating an imaging body of a digital camera. The mode can be switched to the torch mode by reducing the operating current.

The light-emitting device according to the third embodiment can use both spontaneous emission light and stimulated emission light, and can improve power conversion efficiency as wall-plug efficiency. Moreover, by using each of the spontaneous emission light and the stimulated emission light properly depending on the intended use, a single light-emitting device can be used in a plurality of desired applications.

Although the semiconductor light-emitting element 101 according to the first modification of the first embodiment is used as a semiconductor light-emitting element in the present embodiment, the present invention is not limited to this. The present embodiment may use the semiconductor light-emitting element as shown in the first and second embodiments, which has an optical waveguide functioning as an SLD or LD in a part of the semiconductor light-emitting element. Although the semiconductor light-emitting element having an emission wavelength closer to 405 nm is used in the present embodiment, the present invention is not limited to this. For example, a semiconductor light-emitting element that emits light of 450 nm to 470 nm may be used. Although the phosphor layer 560 includes three kinds of phosphor that emit red, green, and blue fluorescence, the present invention is not limited to this. For example, a combination of two kinds of phosphor that emit blue and yellow fluorescence may be used. In the case of using a semiconductor light-emitting element that emits light having an emission wavelength of 450 nm to 470 nm, two kinds of phosphor that emit green and red fluorescence may be used, or one kind of phosphor that emits yellow fluorescence may be used. Examples of the phosphor that emits yellow fluorescence are YAG (Yttrium Aluminium Garnet):Ce, α-SiAlON:Eu, etc.

For example, integral phosphor-containing glass comprised of a mixture of low melting-point glass and the phosphor or phosphors may be used as the cover glass 52 and the phosphor layer 560.

### Fourth Embodiment

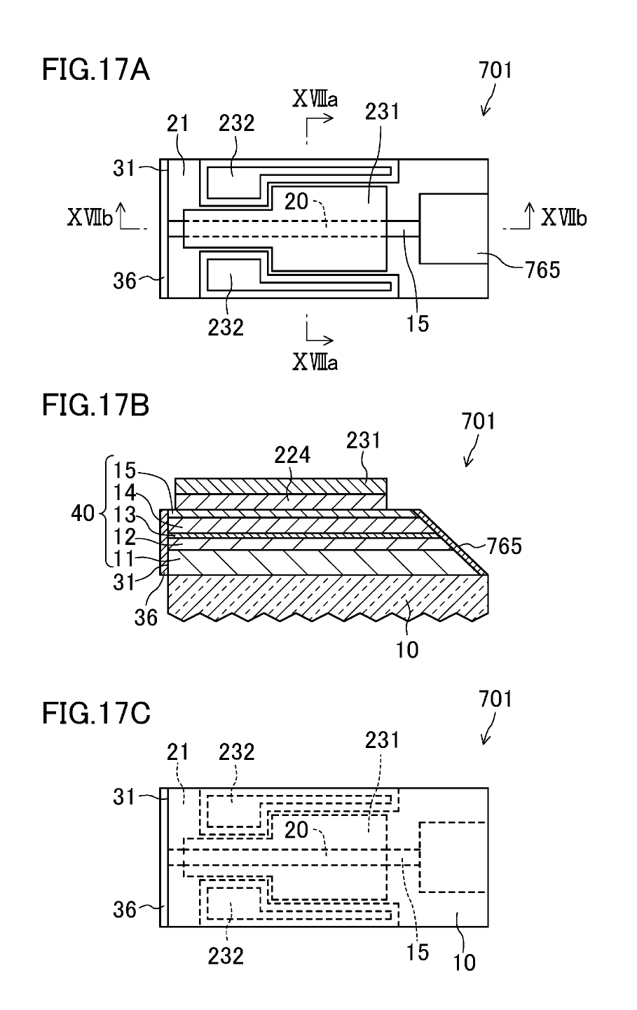

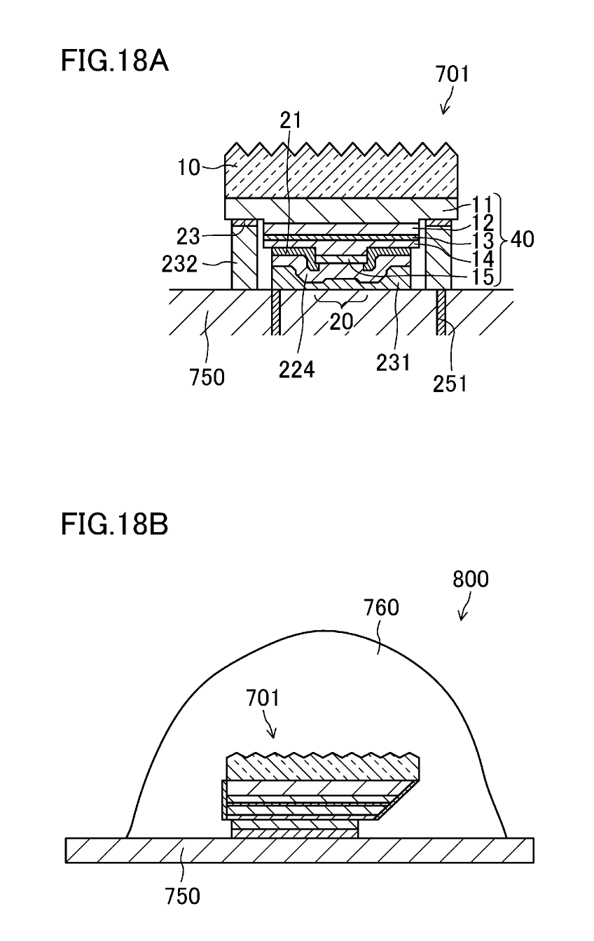

A semiconductor light-emitting element of a fourth embodiment will be described with reference to FIGS. 17A-17C and 18A. In the present embodiment, description of the same portions as those of the first embodiment, the second embodiment, and their modifications is omitted, and only the portions different from those of the first embodiment, the second embodiment, and their modifications will be described. As shown in FIGS. 17A-17C and 18A, in a semiconductor light-emitting element 701 according to the present embodiment, the SLD according to the first modification of the first modification is configured similarly to the second embodiment, and is mounted on a package 750 by junction down mounting.

Specifically, in a semiconductor light-emitting element 701 of the present embodiment, the front end facet is a tilted end facet 765 that is tilted by about 45° with respect to the direction perpendicular to the substrate surface. A fine structure in which triangular pyramids having a height of about 250 mm are arranged in a two-dimensional period (triangular lattice arrangement having a period of about 100 nm) is formed on the rear surface of the substrate 10 (the surface on the opposite side from the surface on which the nitride semiconductor stacked film 40 is formed).

A light-emitting device according to the fourth embodiment will be described with reference to FIGS. 18A-18B. As shown in FIGS. 18A-18B, in a light-emitting device 800 of the present embodiment, the semiconductor light-emitting element 701 is held on the package 750, and is enclosed so as to be covered by a phosphor 760 comprised of silicone containing three kinds of phosphor particles, namely a phosphor emitting red fluorescence, a phosphor emitting green fluorescence, and a phosphor emitting blue fluorescence. Unlike the packages of the first to third embodiments, the package 750 has no reflecting surface for the guided light.

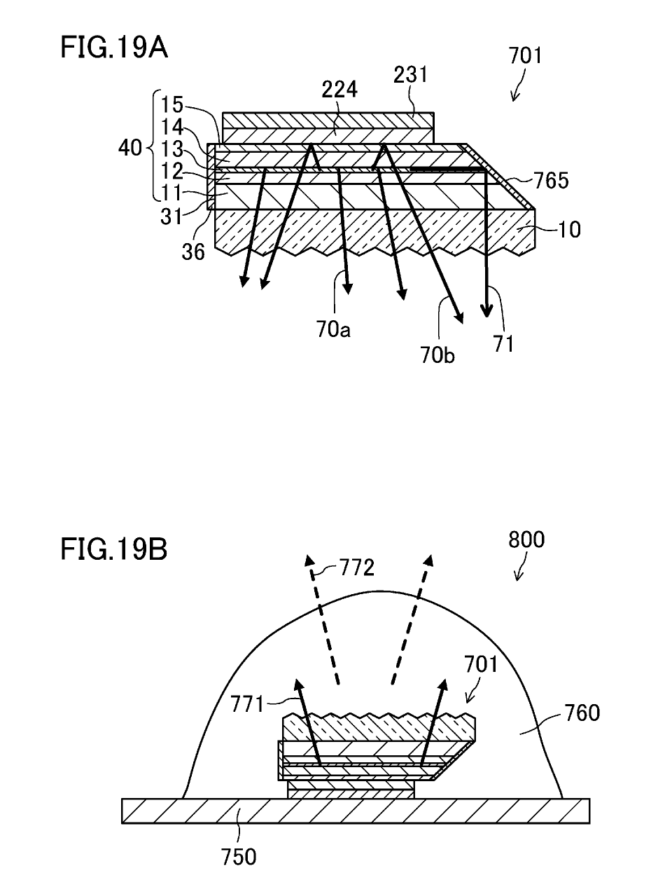

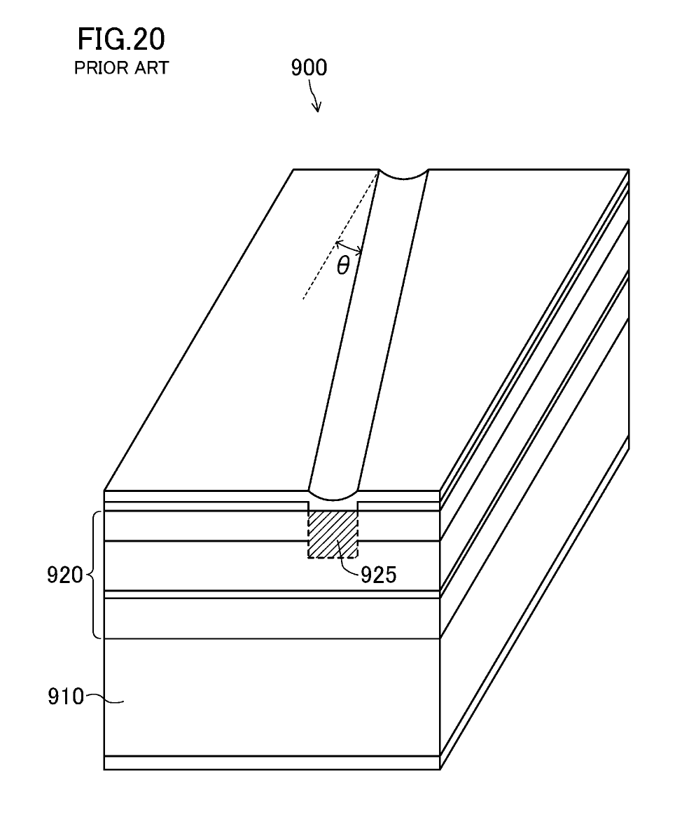

Operation of the semiconductor light-emitting element of the fourth embodiment will be described with reference to FIG. 19A. As shown in FIG. 19A, guided light 71 is reflected toward the substrate 10 by the tilted end face 765, and is emitted to the outside of the semiconductor light-emitting element 701. Non-guided light 70a is emitted upward from the light-emitting layer 13, and non-guided light 70b is emitted downward from the light-emitting layer 13 and is reflected upward by the high reflectance P-side electrode 224. The non-guided light 70a, 70b is thus emitted from the substrate 10 side of the semiconductor light-emitting element 701 to the outside.

Operation of the light-emitting device of the fourth embodiment will be described with reference to FIG. 19B. As shown in FIG. 19B, since the fine structure that is sufficiently smaller than the wavelength is formed on the rear surface of the substrate 10, the refractive index gradually changes at the interface between the substrate 10 and the phosphor 760, which reduces Fresnel reflection resulting from the difference in refractive index between the substrate 10 and the phosphor 760. This reduces reflection of light that propagates in the thickness direction of the substrate. That is, the guided light 71 is not reflected by the rear surface of the substrate 10 and propagates into the phosphor 760. Since the guided light 71 reflected by the tilted end facet 765 thus does not return to the optical waveguide 20, the semiconductor light-emitting element 701 operates as an SLD. The non-guided light 70a, 70b that propagates toward the upper cladding layer 14 and the lower cladding layer 12 is also hardly reflected by the rear surface of the substrate 10 and transmits through the rear surface of the substrate 10 into the phosphor 760. The guided light 71 and the non-guided light 70a, 70b which are incident on the phosphor 760 serve as exciting light 771 to cause RGB emission of the phosphor particles, thereby producing fluorescence 772. The light-emitting device according to the present embodiment thus functions as a white light source.

The semiconductor light-emitting element and the light-emitting device according to the fourth embodiment can use both spontaneous emission light and stimulated emission light, and can improve power conversion efficiency as wall-plug efficiency. Moreover, the semiconductor light-emitting element and the light-emitting device according to the fourth embodiment can be used as a white light source.

The configuration having the tilted end facet as in the fourth embodiment can also be used in a semiconductor light-emitting element that is mounted by junction up mounting as in the first embodiment, by tilting the tilted end side in the opposite direction from the fourth embodiment. Although the front end facet is tilted in the present embodiment, the rear end facet may be tilted, or both the front end facet and the rear end facet may be tilted.

The present embodiment shows an example of the semiconductor light-emitting element and the phosphors. However, the present embodiment may use various combinations of the emission wavelength and the fluorescence wavelength, and may use various combinations of the phosphor materials, as shown in the third embodiment.

In the first to fourth embodiments, the optical waveguide is formed by forming the ridge stripe portion. However, the optical waveguide may be formed by diffusion of impurities such as zinc as in, e.g., the configuration shown in Gerald A. Alphose, Dean B. Gibert, M. G. Harvey, and Michael Ettenberg, IEEE Journal of Quantum Electronics, 1988, Vol. 24, No. 12, page 2454, or may be formed by other methods.

In the configuration described above, the protective film is formed on the end facet of the optical waveguide in order to control reflectance of the guided light and to ensure reliability of the element. However, the protective film may not be formed on the end facet of the optical waveguide. Moreover, in the configuration described above, the film having high reflectance and extending perpendicularly to the optical waveguide is formed on the rear end facet of the optical waveguide in order to obtain high luminous efficiency. However, both the front and rear end facets of the optical waveguide may be tilted with respect to the lateral direction of the optical waveguide.

The first to fourth embodiments are described with respect to a blue-violet LD or SLD in which the nitride semiconductor stacked film is formed on the sapphire substrate. However, a GaN substrate and a Si substrate may be used. The present invention is effective in improving efficiency of semiconductor light-emitting elements using stimulated emission, such as an LD and SLD using a nitride semiconductor and emitting light having a emission wavelength of the ultraviolet range (wavelength of less than 400 nm) or an emission wavelength of the visible range such as blue (wavelength close to 480 nm) and green (wavelength close to 560 nm), or an LD and SLD using other semiconductor material and emitting light having an emission wavelength of red (wavelength close to 620 nm), infrared (wavelength of 700 nm or more), etc.

The semiconductor light-emitting element and the light-emitting device using the same according to the present disclosure can use both spontaneous emission light and stimulated emission light and can improve power conversion efficiency, and are particularly useful as semiconductor light-emitting elements having an optical waveguide that can be applied to switch lighting of electronic equipment, light sources for displays such as a liquid crystal television and a projector, general lighting, and flash light sources of mobile electronic devices, etc.

What is claimed is:

1. A semiconductor light-emitting element, comprising:
a substrate;
a semiconductor stacked film that includes a first cladding layer of a first conductivity type formed on the substrate, a light-emitting layer formed on the first cladding layer, and a second cladding layer of a second conductivity type formed on the light-emitting layer, and that has an optical waveguide;
a first electrode formed so as to be electrically connected to the first cladding layer; and
a second electrode formed so as to be electrically connected to the second cladding layer, wherein
the light-emitting layer generates guided light that is guided in the optical waveguide, and non-guided light that is not guided in the optical waveguide, and
the non-guided light is emitted from one of the substrate side and the semiconductor stacked layer side to outside.

2. The semiconductor light-emitting element of clam 1, wherein
the second electrode includes a transparent electrode comprised of a material that is transparent to the guided light and the non-guided light.

3. The semiconductor light-emitting element of claim 2, wherein
the second electrode includes a non-transparent electrode formed on a region of the transparent electrode other than the optical waveguide, and comprised of a material that is not transparent to the guided light and the non-guided light.

4. The semiconductor light-emitting element of claim 1, further comprising:
a reflecting portion formed below the light-emitting layer and configured to reflect the non-guided light.

5. The semiconductor light-emitting element of claim 4, wherein
the reflecting portion includes a reflecting film comprised of a metal and formed on a surface of the substrate which is located on an opposite side from a surface on which the semiconductor stacked film is formed.

6. The semiconductor light-emitting element of claim 4, wherein
the reflecting portion includes a film formed on the substrate and comprised of a material having a different refractive index from that of the semiconductor stacked film.

7. The semiconductor light-emitting element of claim 4, wherein
the reflecting portion includes a recess formed in an upper part of the substrate.

8. The semiconductor light-emitting element of claim 1, wherein
an end facet of the optical waveguide is tilted with respect to a direction perpendicular to a surface of the substrate.

9. The semiconductor light-emitting element of claim 1, wherein
the substrate is comprised of a material that is transparent to the guided light and the non-guided light.

10. The semiconductor light-emitting element of claim 9, wherein
the second electrode is comprised of a material that reflects the non-guided light.

11. The semiconductor light-emitting element of claim 9, wherein
the first electrode includes a non-transparent electrode comprised of a material that is not transparent to the guided light and the non-guided light, and
the non-transparent electrode has an opening below the optical waveguide.

12. The semiconductor light-emitting element of claim 9, wherein
the substrate includes a concavo-convex portion having a one-dimensional period or a two-dimensional period on its surface that is located on an opposite side from a surface on which the semiconductor stacked film is formed.

13. The semiconductor light-emitting element of claim 9, wherein
an end facet of the optical waveguide is tilted with respect to a direction perpendicular to a surface of the substrate.

14. A light-emitting device, comprising:
the semiconductor light-emitting element of claim 1; and
a package configured to hold the semiconductor light-emitting element, wherein
the semiconductor light-emitting element is held such that its surface on the substrate side contacts the package, and
the guided light and the non-guided light which are emitted from the semiconductor light-emitting element are emitted from an upper side of the package to the outside.

15. A light-emitting device, comprising:
the semiconductor light-emitting element of claim 1; and
a package configured to hold the semiconductor light-emitting element, wherein
the semiconductor light-emitting element is held such that its surface on the semiconductor stacked film side contacts the package, and
the guided light and the non-guided light which are emitted from the semiconductor light-emitting element are emitted from an upper side of the package to the outside.

16. The light-emitting device of claim 14, wherein
the package has a recessed shape having a bottom surface and a sidewall surface, and
the sidewall surface is tilted so as to form an obtuse angle with the bottom surface, and is configured to reflect the guided light.

17. The light-emitting device of claim 14, further comprising:
a member provided over the package and including a phosphor.

18. The light-emitting device of claim 14, wherein
the light-emitting device is configured to be selectable between a first operation of emitting the guided light and the non-guided light and a second operation of emitting only the non-guided light.

19. The light-emitting device of claim 18, wherein
the first operation is selected when an amount of current flowing in the semiconductor light-emitting element is larger than a threshold current, and
the second operation is selected when the amount of current flowing in the semiconductor light-emitting element is smaller than the threshold current.
